(19) United States
(12) Patent Application Publication
(10) Pub. No.: US 2026/0202477 A1
(43) Pub. Date: Jul. 16, 2026

(54) A METHOD FOR LEARNING AN ANALYSIS MODEL OF AN IMPACT ON A BATTERY MODULE AND A METHOD FOR PREDICTING AN ANALYSIS RESULT OF THE IMPACT ON THE BATTERY MODULE

(71) Applicant: LG ENERGY SOLUTION, LTD., Seoul (KR)

(72) Inventor: Seungho SONG, Daejeon (KR)

(21) Appl. No.: 19/128,021

(22) PCT Filed: Dec. 7, 2023
(86) PCT No.: PCT/KR2023/020092

§ 371 Date: May 7, 2025

(30) Foreign Application Priority Data
Dec. 13, 2022 (KR) 10-2022-0174030

(51) Int. Cl. G01R 31/367; G01R 31/382

(52) U.S. Cl. CPC G01R 31/367; G01R 31/382

(57) ABSTRACT

A method for learning an analysis model of an impact on a battery module according to one embodiment of the present disclosure includes the steps of: sampling an initial state value of the battery module and a deformed state value of the battery module according to an impact value applied to the battery module; repeating the sampling step during a predetermined test period to acquire learning data; and receiving input of the initial state value of the battery module and the impact value applied to the battery module by the number of times of sampling and machine learning an impact analysis model of a battery module so as to predict an analysis result of the battery module due to an impact.

### CROSS-REFERENCE TO RELATED APPLICATIONS

This application is a National Phase entry pursuant to 35 U.S.C. 371 of International Patent Application No. PCT/KR2023/020092 filed on Dec. 7, 2023, which claims priority to Korean Patent Application No. 10-2022-0174030 filed in the Korean Intellectual Property Office on Dec. 13, 2022. The contents of the aforementioned applications are incorporated by reference herein in their entireties.

### TECHNICAL FIELD

The present disclosure relates to a method for learning an analysis model of an impact on a battery module and a method for predicting an analysis result of the impact on the battery module, and more specifically, to a method for rapidly predicting an impact stability of the battery module by applying a machine learning technique.

### BACKGROUND

Verification of structural safety in specific impact situations is essentially required in the development of battery modules. A method generally used heretofore is to perform a finite element analysis.

Impact analysis results obtained through the finite element analysis are relatively accurate, however, have a disadvantage that modeling and calculations are labor-intensive and time-consuming, and specialized software for structural analysis must be used.

Meanwhile, there are frequent design changes in an early stage of development, and operational inefficiency occurs while repeating this process for each change. In the process of designing and developing a battery module, including the early stage of development of the battery module, a method that can predict the impact stability of the battery module within a rapid time is required.

The background description provided herein is for the purpose of generally presenting context of the disclosure. Unless otherwise indicated herein, the materials described in this section are not prior art to the claims in this application and are not admitted to be prior art, or suggestions of the prior art, by inclusion in this section.

### SUMMARY

It is an object of the present disclosure to provide a method for predicting a stability of the battery module, particularly a method for rapidly predicting an impact stability of the battery module by applying a machine learning technique.

However, the technical problems to be solved by embodiments of the present disclosure are not limited to the above-described problems, and can be variously expanded within the scope of the technical idea included in the present disclosure.

According to one embodiment of the present disclosure, there is provided a method for predicting an analysis result of an impact on a battery module performed by a battery module evaluation system that comprises an impact analysis model of a battery module, the method comprising the steps of: receiving, by the impact analysis model, inputs identifying an initial state value of the battery module and an impact value applied to the battery module; and predicting, by the impact analysis model, an analysis result of the battery module due to impact from an impact analysis model of the battery module based, at least in part, on the initial state value and the impact value.

The method for predicting an analysis result of an impact on a battery module further comprises executing a learning procedure to derive an analysis model of an impact on a battery module applied to the battery module evaluation system, wherein executing the learning procedure comprises: executing a sampling step that samples initial state values corresponding to one or more battery modules and deformed state values corresponding to the one or more battery modules, wherein the deformed state values are determined based on impact values derived in response to impacts applied to the one or more battery modules; repeating the sampling step during a predetermined test period to acquire learning data; and applying a machine learning process to derive the impact analysis model for analyzing the battery module based, at least in part, on the learning data, wherein the machine learning process utilizes the initial state values and the deformed state values for the one or more battery modules to train the impact analysis model to predict the analysis result of the battery module due to the impact.

The sampling step may comprise measuring and storing the initial state values for the one or more battery modules; storing the impact values correspond to the one or more battery modules; and measuring and storing the deformed state values for the one or more battery modules derived in response to the impacts to the one or more battery modules.

The step of predicting an analysis result of the battery module may comprise predicting the deformed state value of the battery module due to the impact.

The method for predicting an analysis result of an impact on a battery module may comprise predicting a strain of the battery module based, at least in part, on the deformed state value of the battery module.

The initial state value of the battery module is derived from a predetermined portion of the battery module, and the deformed state value of the battery module is derived from a predetermined portion of the battery module.

The strain of the battery module may be a plastic strain of the battery module due to the impact.

The strain of the battery module may be a strain of a predetermined portion of the battery module.

The strain (εₚ) of the battery module is a value obtained by subtracting the elastic strain (εₑ) from the total strain (ε) at the time of impact of the battery module, and follows the following Mathematical Equations 1 to 3,

$${ε}_{p} = ε - {ε}_{e} \qquad [ Mathematical Equation 1 ]$$

$$ε = {\int }_{{L}_{0}}^{L} \frac{dL}{L} = ln ( \frac{L}{{L}_{0}} ) \qquad [ Mathematical Equation 2 ]$$

$${ε}_{e} = σ / E \qquad [ Mathematical Equation 3 ]$$

wherein, L₀ is a dimension of the battery module before deformation, L is a dimension of the battery module after deformation, σ is a stress value when a material is in its elastic limit state, and E is an elastic modulus of the material.

The method for predicting an analysis result of an impact on a battery module may further comprise predicting a SCORE indicating the danger degree of the battery module from the strain of the battery module.

The SCORE indicating the danger degree of the battery module follows the following Mathematical Equation 4,

$$( SCORE ) = 1 / ( 1 + Exp ( - 645.62 {ε}_{p}^{3} + 312.85 {ε}_{p}^{2} - 61.417 {ε}_{p} + 2.9444 ) ) \qquad [ Mathematical Equation 4 ]$$

wherein, the SCORE may be a value between 0 and 1.

If the SCORE is less than 0.4, it is determined that the danger degree due to impact of the battery module is “safe”, if the SCORE is greater than 0.6, it is determined that the danger degree due to impact of the battery module is “dangerous”, and if the SCORE is 0.4 or more and 0.6 or less, determination of the danger degree due to impact of the battery module may be suspended.

For example, if the SCORE is less than 0.4, the danger degree due to the impact of the battery module can be assigned or determined to be a first safety rating indicating a safe state for the battery module. If the SCORE is greater than 0.6, the danger degree due to the impact of the battery module can be assigned or determined to be a second safety rating indicating a dangerous state for the battery module. If the SCORE is equal to or falls with a range of 0.4 and 0.6, a determination of the danger degree due to impact of the battery module is held or suspended.

The initial state value of the battery module includes an initial dimension value of the battery module, the impact value comprises a deformed state value corresponding to the battery module, and the deformed state value of the battery module may include a deformed dimension value of the battery module after deformation.

The initial and/or deformed dimension values of the battery module may include at least one of the length, width, height, upper face thickness, lower face thickness, and side face thickness of a predetermined portion of the battery module.

The initial state value of the battery module may include at least one of the density of the battery cells included in the battery module and the mass of the battery cells.

The impact value applied to the battery module may include at least one of an impact size and a duration during which the impact is applied.

According to another embodiment of the present disclosure, there is provided a battery module evaluation system which performs the method for predicting an analysis result of an impact on a battery module, the battery module evaluation system comprising: a data input unit that receives input of an initial state value of the battery module and an impact value applied to the battery module; a data processing unit that executes an impact analysis model of the battery module to derive an analysis result of the impact based, at least in part, on the initial state value and the impact value; and a data output unit that outputs an analysis result of the battery module.

The battery module evaluation system may further comprise a data storage unit that stores an impact analysis model of the battery module.

According to yet another embodiment of the present disclosure, there is provided a method for learning an analysis model of an impact on a battery module, the method comprising the steps of: sampling an initial state value of the battery module and a deformed state value of the battery module according to an impact value applied to the battery module; repeating the sampling step during a predetermined test period to acquire learning data; and receiving input of the initial state value of the battery module and the impact value applied to the battery module by the number of times of sampling and machine learning an impact analysis model of a battery module so as to predict an analysis result of the battery module due to an impact.

According to another embodiment of the present disclosure, a method is provided for learning an analysis model for predicting an analysis result based on an impact on a battery module. The method can comprise the steps of: (a) generating learning data during a predetermined test period by sampling an initial state value of one or more battery modules and a deformed state value of the one or more battery modules, wherein the deformed state value of the one or more battery modules is determined based from an impact value derived after an impact to the one or more battery modules; executing a machine learning process to generate an impact analysis model for predicting an analysis result based on an impact of a battery module, wherein the machine learning process utilizes the learning data to train the impact analysis model.

In certain embodiments, sampling the initial state value of the one or more battery modules and the deformed state value of the one or more battery modules includes: measuring and storing the initial state value of the one or more battery modules; storing the impact value corresponding to the one or more battery modules and measuring and storing the deformed state value of the one or more battery modules due to the impact.

In certain embodiments, executing the machine learning process comprises calculating a strain of the one or more battery modules based, at least in part, on the deformed state value of the one or more battery module.

In certain embodiments, the initial state value of the one or more battery modules corresponds to a predetermined portion of the one or more battery modules, and the deformed state value of the one or more battery modules corresponds to the predetermined portion of the one or more battery modules.

In certain embodiments, the strain of the one or more battery modules corresponds to a plastic strain and/or an elastic strain of the one or more battery modules due to the impact.

In certain embodiments, the strain of the one or more battery modules corresponds to a predetermined portion of the one or more battery modules.

The sampling step may comprise measuring an initial state value of the battery module and storing it; storing an impact value applied to the battery module; and measuring a deformed state value of the battery module due to the impact and storing it.

The initial state value of the battery module may be an initial state value of a predetermined portion of the battery module, and the deformed state value of the battery module may be a deformed state value of a predetermined portion of the battery module.

The machine learning step may comprise calculating a strain of the battery module from the deformed state value of the battery module and storing it.

The strain of the battery module may be a plastic strain of the battery module due to the impact.

The strain of the battery module may be a strain of a predetermined portion of the battery module.

The strain (εₚ) of the battery module is a value obtained by subtracting the elastic strain (εₑ) from the total strain (ε) at the time of impact of the battery module, and follows the following Mathematical Equations 1 to 3,

$${ε}_{p} = ε - {ε}_{e} \qquad [ Mathematical Equation 1 ]$$

$$ε = {\int }_{{L}_{0}}^{L} \frac{dL}{L} = ln ( \frac{L}{{L}_{0}} ) \qquad [ Mathematical Equation 2 ]$$

$${ε}_{e} = σ / E \qquad [ Mathematical Equation 3 ]$$

wherein, L₀ is a dimension of the battery module before deformation, L is a dimension of the battery module after deformation, σ is a stress value when the material of the battery module is in its elastic limit state, and E is an elastic modulus of the material of the battery module.

The machine learning step may further comprise calculating a SCORE indicating the danger degree of the battery module from the strain of the battery module and storing it.

The SCORE indicating the danger degree of the battery module may follow the following Mathematical Equation 4,

$$( SCORE ) = 1 / ( 1 + Exp ( - 645.62 {ε}_{p}^{3} + 312.85 {ε}_{p}^{2} - 61.417 {ε}_{p} + 2.9444 ) ) \qquad [ Mathematical Equation 4 ]$$

wherein, the SCORE may be a value between 0 and 1.

If the SCORE is less than 0.4, it is determined that the danger degree due to impact of the battery module is “safe”, if the SCORE is greater than 0.6, it is determined that the danger degree due to impact of the battery module is “dangerous”, and if the SCORE is 0.4 or more and 0.6 or less, determination of the danger degree due to impact of the battery module may be suspended.

The initial state value of the battery module may include an initial value of the dimension of the battery module, and the deformed state value of the battery module may include the dimension value of the battery module after deformation.

The dimension value of the battery module may include at least one of the length, width, height, upper face thickness, lower face thickness, and side face thickness of a predetermined portion of the battery module.

The initial state value of the battery module may include at least one of the density of the battery cells included in the battery module and the mass of the battery cells.

The impact value applied to the battery module may include at least one of an impact size and a duration during which the impact is applied.

The impact size may be expressed by the acceleration of the object that applies impact to the battery module.

The method for learning an analysis model of an impact on a battery module may further comprise verifying effectiveness of the impact analysis of the battery module, wherein the verifying effectiveness comprises: generating, as verification data, an initial state value of the battery module and a deformed state value of the battery module according to an impact value applied to the battery module during a predetermined verification period; calculating an analysis result of the battery module from an impact analysis model of the battery module using the verification data; calculating an analysis result of the battery module according to the initial state value of the battery module and the impact value applied to the battery module using the verification data through finite element analysis; and determining that the impact analysis model of the battery module is valid, when the difference between the analysis result of the battery module predicted from the impact analysis model of the battery module and the analysis result of the battery module calculated through the finite element analysis is within a predetermined reference value range.

According to the present disclosure, it is possible to rapidly predict the impact stability of the battery module, and as a result, the design and development of the electrode module can be carried out efficiently.

In addition, conditions and prediction results for the impact stability of the battery module can be standardized. Thereby, the reliability in quality of the manufactured battery module can be ensured.

Effects obtainable from the present disclosure are not limited to the effects mentioned above, and additional other effects not mentioned herein will be clearly understood from the description of the appended claims by those skilled in the art.

### BRIEF DESCRIPTION OF THE DRAWINGS

The accompanying drawings illustrate a preferred embodiment of the present disclosure and together with the foregoing disclosure, serve to provide further understanding of the technical features of the present disclosure, and thus, the present disclosure is not construed as being limited to the drawings.

FIG. 1 is a block diagram illustrating a battery module evaluation system according to an embodiment of the present disclosure.

FIG. 2 is a flowchart illustrating a method of learning an impact analysis model of a battery module performed in the battery module evaluation system according to an embodiment of the present disclosure.

FIG. 3 is a flowchart illustrating a method for predicting an analysis result of the impact on a battery module performed by the battery module evaluation system including an impact analysis model of the battery module according to an embodiment of the present disclosure.

FIG. 4 is an analysis result of the impact on a battery module according to an embodiment of the present disclosure, and graphically shows the SCORE calculated according to the strain of the battery module.

### DETAILED DESCRIPTION

Hereinafter, embodiments disclosed in the present specification will be described in detail with reference to the accompanying drawings, however, identical or similar elements are assigned identical reference numerals regardless of reference numerals, and a redundant description thereof will be omitted.

The suffixes “module” and/or “part” of elements used in the description below are assigned or used only in consideration of the ease of description of the specification, and the suffixes themselves do not have meanings or roles distinguished from each other. In addition, a term such as “ . . . part”, “ . . . unit”, and “module” described in the specification means a unit for performing at least one function or operation, which can be embodied by hardware, by software, or by a combination of hardware and software.

In the following description of the present disclosure, a detailed description of known functions and configurations incorporated herein will be omitted when it may make the subject matter of the present disclosure unclear. In addition, the accompanying drawings are only for easy understanding of the embodiments disclosed in the present specification, however, the technical idea disclosed herein is not limited by the accompanying drawings and should be construed as including all changes, equivalents and substitutes included in the spirit and scope of the present disclosure.

In this specification, terms such as “include” or “have” are intended to designate that the features, numbers, steps, operations, components, parts, or combinations thereof described in the specification exist, but it should be understood that this does not preclude the existence or addition of one or more other features, numbers, steps, operations, components, parts, or combinations thereof.

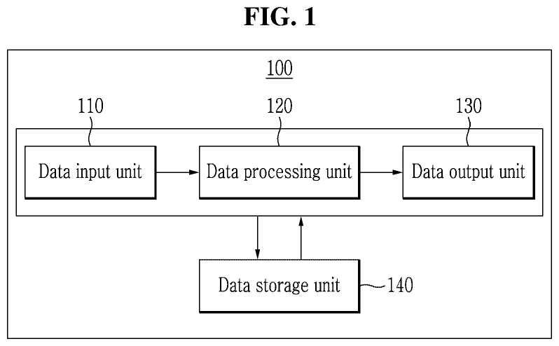

FIG. 1 is a block diagram illustrating a battery module evaluation system 100 according to an embodiment of the present disclosure. The battery module evaluation system 100 according to an embodiment of the present disclosure includes a data input unit 110, a data processing unit 120, and a data output unit 130.

The data input unit 110 may be, for example, an input device of a mobile device, an input device of a computer, various keyboards, a mouse, an electronic pen, a microphone, etc. and suffices if it is a unit that can receive input of other data.

The data processing unit 120 receives input of learning data, and performs machine learning on an impact analysis model of the battery module according to an embodiment of the present disclosure, while in predicting the analysis result of the impact on the battery module, it can receive input of the initial state value of the battery module and the impact value applied to the module, and predict the analysis result of the impact on the battery module using the impact analysis model of the battery module. The data processing unit 120 may be, for example, a processor of a mobile device, a processor of a computer, and the like, and suffices if it is a device capable of performing the method for learning an analysis model of the impact on a battery module and the method for predicting the analysis result of the impact on the battery module according to an embodiment of the present disclosure.

The data output unit 130 outputs the results processed by the data processing unit 120. For example, it may be an output device of a mobile device, an output device of a computer, various display devices, various speaker units, and the like, and suffices if it is a unit that can output other data.

The data storage unit 140 can store the impact analysis model for the battery module according to an embodiment of the present disclosure, and also store learning data, data input to the data input unit 110, processing results in the data processing unit 120, other various data, and the like.

The data input unit 110, the data processing unit 120, the data output unit 130, and the data storage unit 140 may all be integrated into one device, and in some cases, at least one of the data input unit 110, the data processing unit 120, the data output unit 130, and the data storage unit 140 may be remotely connected to and controlled by other components.

The analysis model of an impact on a battery module according to an embodiment of the present disclosure can be acquired through machine learning.

First, a method for learning an analysis model of an impact on a battery module will be described.

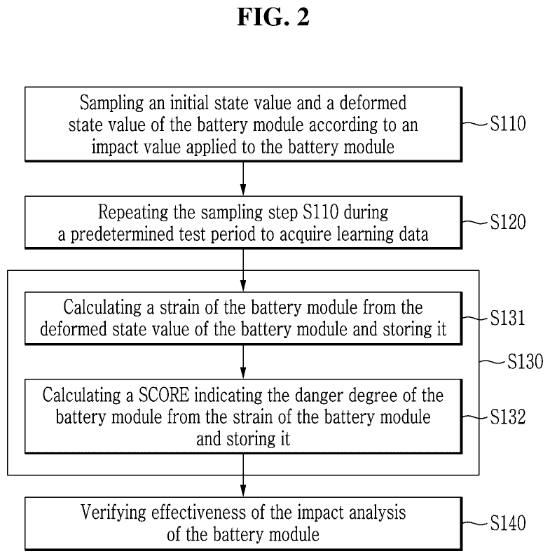

FIG. 2 is a flowchart illustrating a method of learning an analysis model of an impact on a battery module performed in the battery module evaluation system 100 according to an embodiment of the present disclosure.

First, the data processing unit 120 performs a step S110 of sampling an initial state value of the battery module and the deformed state value of the battery module according to an impact value applied to the battery module. In step S110, the data input unit 110 receives input of the initial state value of the battery module and the impact value applied to the battery module, and the data processing unit 120 performs step S110.

Further, the data sampled in step S110 is stored in the data storage unit 140. More specifically, it comprises a step (S111) of measuring an initial state value of the battery module and storing it in the data storage unit 140; a step (S112) of applying an impact to the battery module and storing the impact value applied to the battery module in the data storage unit 140; and a step (S113) of measuring a deformed state value of the battery module due to the impact and storing it in the data storage unit 140.

Here, the initial state value of the battery module means the initial state value of a predetermined portion of the battery module. The predetermined portion of the battery module may be a portion of the battery module that is prespecified (preset) as desired by an operator in accordance with the process, environment, and the like. This is because, when an impact is applied to the battery module, the dimensions and other conditions of the battery module may be deformed mainly in the area where the impact is applied. However, the present disclosure is not limited to those set forth above, and a predetermined portion of the battery module may be the entire battery module. Further, the initial state value of the battery module includes the initial dimension value of the battery module. The deformed state value of the battery module due to impact means the deformed state value of a predetermined portion of the battery module. In addition, the deformed state of a predetermined portion of the battery module includes a dimension value in which the initial dimension has been deformed due to an impact applied to the battery module.

The dimension value of the battery module means the dimension value of a predetermined portion of the battery module. The dimension value of the battery module (i.e., the dimension value of a predetermined portion of the battery module) includes at least one of the length, width, height, upper face thickness, lower face thickness, and side face thickness of a predetermined portion of the battery module. With regard to detailed factors included in the dimension values of the battery module, the present disclosure is not limited to those set forth above, and the factors can be set in various ways in accordance with different environments and/or in accordance with the conditions desired or specified by an operator.

For example, the total length, width and height of the battery module may be set as the dimension values of the battery module, however, if the battery module consists of a U frame and a top plate that covers it, various variations and changes can be made, such as being able to set the length, width and height of the U frame alone as the dimension values of the battery module, and being able to set the length, width and height of the top plate alone as the dimension values of the battery module. In addition, it is possible to take into account only the dimension values for the frame or plate, focusing on the portion where impact is applied.

Further, the initial state value of the battery module includes at least one of the density of the battery cells included in the battery module and the mass of the battery cells.

The impact value applied to the battery module includes at least one of an impact size and a duration during which the impact is applied. An example of factors (physical quantities) representing the impact size includes the acceleration of the object that impacts the battery module. However, the present disclosure is not limited to those set forth above, and the impact of the battery module can be analyzed by selecting various physical quantities indicating the impact size so as to match with a desired environment and/or the conditions desired or specified by an operator.

The deformed status value of the battery module due to impact may be status information such as temperature change, ignition, explosion, and the like of the battery module, depending on the case.

The data processing unit 120 repeats the sampling step (S110) for a predetermined test period to acquire learning data (S120). In step S120, similarly, the data input unit 110 receives input of the initial state value of the battery module and the impact value applied to the battery module, and the data processing unit 120 performs step S120. Further, the learning data acquired in step S120 is stored in the data storage unit 140.

The data processing unit 120 receives input of the initial state value of the battery module and the impact value applied to the battery module by the number of times of sampling and performs a step (S130) of machine learning an impact analysis model of a battery module so as to predict an analysis result of the battery module due to an impact.

Step S130 includes a step (S131) of calculating the strain of the battery module from the deformed state value of the battery module through the data processing unit 120 and storing it in the data storage unit 140.

At this time, the strain of the battery module refers to the strain of a predetermined portion of the battery module. For predetermined portions of the battery module, refer to the portions set forth above.

Further, the strain of the battery module means a plastic strain (εₚ) of the battery module due to the impact. The strain (εₚ) of the battery module is a value obtained by subtracting the elastic strain (εₑ) from the total strain (ε) at the time of impact of the battery module, and follows the following Mathematical Equations 1 to 3,

$${ε}_{p} = ε - {ε}_{e} \qquad [ Mathematical Equation 1 ]$$

$$ε = {\int }_{{L}_{0}}^{L} \frac{dL}{L} = ln ( \frac{L}{{L}_{0}} ) \qquad [ Mathematical Equation 2 ]$$

$${ε}_{e} = σ / E \qquad [ Mathematical Equation 3 ]$$

wherein, L₀ is a dimension of the battery module before deformation (i.e., the dimension of a predetermined portion of the battery module before deformation), L is a dimension of the battery module after deformation (i.e., the dimension of a predetermined portion of the battery module after deformation). Further, σ is a stress value when the material (material of the battery module, i.e. material of a predetermined portion of the battery module) is in its elastic limit state, and E is the elastic modulus of the material. When a material (material of the battery module, i.e. material of a predetermined portion of the battery module) is in a deformation that does not exceed its elastic limit, stress and strain have a linear relationship with each other, and the slope is called the elastic modulus. Each of o and E is a value unique to the battery module to be inspected (i.e., the material of the battery module) and is input as a preset value. Alternatively, the elastic strain (εₑ) derived from Mathematical Equation 3 is also a unique value for the battery module to be inspected (i.e., the material of the battery module), so that the elastic strain (εₑ) is input as a preset value. As described above, the dimension of the battery module includes at least one of the length, width, height, upper face thickness, lower face thickness, and side face thickness of a predetermined portion of the battery module.

The strain (εₚ) of each battery module is derived by applying Mathematical Equation 1 to Mathematical Equation 3 to each factor of length, width, height, upper face thickness, lower face thickness, and side face thickness of a predetermined portion of the battery module, and then the average value of the strain (εₚ) of each battery module derived for each factor of the length, width, height, upper face thickness, lower face thickness and side face thickness of a predetermined portion of the battery module may be determined, or alternatively, the maximum value may be determined among the strain (εₚ) of each battery module.

Alternatively, in some cases, only some factors suitable for the environment are selected from among the length, width, height, upper face thickness, lower face thickness and side face thickness of a predetermined portion of the battery module to derive the strain (εₚ) of the battery module, respectively. Similarly, the average value of the strain (εₚ) of each battery module may be determined, or the maximum value may be determined.

Further, step S130 further comprises a step (S132) of calculating a SCORE indicating the danger degree of the battery module from the strain of the battery module calculated in step S131.

For example, the SCORE indicating the danger degree of a battery module follows the following Mathematical Equation 4.

$$( SCORE ) = 1 / ( 1 + Exp ( - 645.62 {ε}_{p}^{3} + 312.85 {ε}_{p}^{2} - 61.417 {ε}_{p} + 2.9444 ) ) \qquad [ Mathematical Equation 4 ]$$

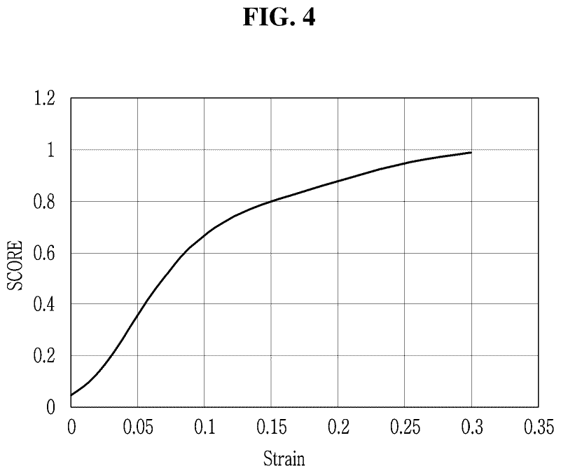

This is a value obtained by arbitrarily scaling the plastic strain (εₚ) of the battery module so that when 0≤the plastic strain (εₚ) of the battery module≤1, the SCORE is a value between 0 and 1 (see FIG. 4).

Mathematical Equation 4 is an example, and the present disclosure is not limited to those set forth above. The SCORE can be adjusted in accordance with the various environments and embodiments.

$$( SCORE ) = 1 / ( 1 + Exp ( {C}_{1} {ε}_{p}^{3} + {C}_{2} {ε}_{p}^{2} + {C}_{3} {ε}_{p} + {C}_{4} ) ) \qquad [ Mathematical Equation 5 ]$$

wherein, C₁, C₂, C₃, C₄ are coefficients.

Further, this can be classified into grades according to the SCORE calculated in step S132.

For example, if the SCORE is less than 0.4, it is determined that the danger degree due to impact of the battery module is “safe”; if the SCORE is greater than 0.6, it is determined that the danger degree due to impact of the battery module is “dangerous”; and if the SCORE is 0.4 or more and 0.6 or less, determination of the danger degree due to impact of the battery module may be suspended. This is an example, and the present disclosure is not limited to those set forth above.

For example, the grade of danger degree may be classified into a different number of grades instead of the three mentioned above, and the range in which the SCORE calculated according to the coefficient value set in Mathematical Equation 5 is scaled also differs. Therefore, various changes and variations can be made, for example, the standard value for dividing grades may be a value other than 0.4 and 0.6 mentioned above.

Further, the data processing unit 120 performs a step (S140) of verifying the effectiveness of the impact analysis of the battery module.

Step S140 can comprise a step of generating, as verification data, an initial state value of the battery module and a deformed state value of the battery module according to an impact value applied to the battery module during a predetermined verification period; a step of calculating an analysis result of the battery module from an impact analysis model of the battery module using the verification data; a step of calculating an analysis result of the battery module according to the initial state value of the battery module and the impact value applied to the battery module using the verification data through finite element analysis; and a step of determining that the impact analysis model of the battery module is valid, when the difference between the analysis result of the battery module predicted from the impact analysis model of the battery module and the analysis result of the battery module calculated through the finite element analysis is within a predetermined reference value range.

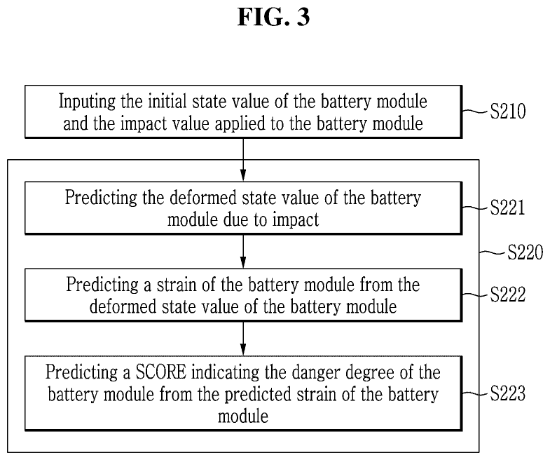

FIG. 3 is a flowchart illustrating a method for predicting an analysis result of the impact on a battery module performed by the battery module evaluation system 100 including an impact analysis model of the battery module according to an embodiment of the present disclosure.

The battery module evaluation system 100 performs the method for learning an analysis model of an impact on a battery module described above with reference to FIG. 2. The analysis model of an impact on a battery module may be acquired through machine learning in the data processing unit 120 and stored in the data storage unit 140. The battery module evaluation system 100 predicts an analysis result of the impact on the battery module through a machine-learned impact analysis model of the battery module according to an embodiment of the present disclosure.

First, the data processing unit 120 performs a step (S210) of receiving input of the initial state value of the battery module and the impact value applied to the battery module.

Here, the initial state value of the battery module includes the initial dimension value of the battery module. The initial dimension value of the battery module includes at least one of the length, width, height, upper face thickness, lower face thickness, and side face thickness of a predetermined portion of the battery module. Further, the initial state value of the battery module includes at least one of the density of the battery cells included in the battery module and the mass of the battery cells. The impact value applied to the battery module includes at least one of the impact size and the duration during which the impact is applied.

A step (S220) of predicting the analysis results of the impact on the battery module from the impact analysis model of the battery module is performed.

Step S220 includes a step (S221) of predicting a deformed state value of the battery module due to impact. Here, the deformed state value of the battery module due to the impact includes the dimension value where the initial dimension is deformed due to the impact applied to the battery module. The deformed dimension value of the battery module, that is, the dimension of the battery module after deformation, includes at least one of the length, width, height, upper face thickness, lower face thickness, and side face thickness of a predetermined portion of the battery module. The deformed state value of the battery module due to impact may be state information such as temperature change, ignition, or explosion of the battery module, depending on the case.

Further, step S220 includes a step (S222) of predicting the strain of the battery module from the deformed state value of the battery module predicted in step S221.

At this time, the strain of the battery module means a plastic strain (εₚ) of the battery module due to impact. The strain (εₚ) of the battery module is a value obtained by subtracting the elastic strain (εₚ) from the total strain (8) at the time of impact of the battery module, and follows the following Mathematical Equations 1 to 3,

$${ε}_{p} = ε - {ε}_{e} \qquad [ Mathematical Equation 1 ]$$

$$ε = {\int }_{{L}_{0}}^{L} \frac{dL}{L} = ln ( \frac{L}{{L}_{0}} ) \qquad [ Mathematical Equation 2 ]$$

$${ε}_{e} = σ / E \qquad [ Mathematical Equation 3 ]$$

wherein, L₀ is a dimension of the battery module before deformation, and L is a dimension of the battery module after deformation. The dimensions of the battery module include at least one of the length, width, height, upper face thickness, lower face thickness, and side face thickness of a predetermined portion of the battery module as described above. The dimension of the battery module can be set by deforming and changing in various ways. Refer to those set forth above with reference to FIG. 2.

The strain (εₚ) of each battery module is derived by applying Mathematical Equation 1 to Mathematical Equation 3 to each factor of length, width, height, upper face thickness, lower face thickness, and side face thickness of a predetermined portion of the battery module, and then the average value of the strain (εₚ) of each battery module derived for each factor of the length, width, height, upper face thickness, lower face thickness and side face thickness of a predetermined portion of the battery module may be obtained, or alternatively, the maximum value may be obtained among the strain (εₚ) of each battery module.

Alternatively, in some cases, only some factors suitable for the environment are selected from among the length, width, height, upper face thickness, lower face thickness and side face thickness of a predetermined portion of the battery module to derive the strain (εₚ) of the battery module, respectively. Similarly, the average value of the strain (εₚ) of each battery module may be determined, or the maximum value may be determined.

Further, step S220 further comprises a step (S223) of calculating a SCORE indicating the danger degree of the battery module from the strain of the battery module predicted in step S222.

For example, the SCORE indicating the danger degree of a battery module follows the following Mathematical Equation 4.

$$( SCORE ) = 1 / ( 1 + Exp ( - 645.62 {ε}_{p}^{3} + 312.85 {ε}_{p}^{2} - 61.417 {ε}_{p} + 2.9444 ) ) \qquad [ Mathematical Equation 4 ]$$

This is a value obtained by arbitrarily scaling the plastic strain (εₚ) of the battery module so that when 0≤the plastic strain (εₚ) of the battery module≤1, the SCORE is a value between 0 and 1 (see FIG. 4).

Mathematical Equation 4 is an example, and the present disclosure is not limited to those set forth above. The SCORE can be adjusted in accordance with the various environments and/or embodiments.

$$( SCORE ) = 1 / ( 1 + Exp ( {C}_{1} {ε}_{p}^{3} + {C}_{2} {ε}_{p}^{2} + {C}_{3} {ε}_{p} + {C}_{4} ) ) \qquad [ Mathematical Equation 5 ]$$

wherein, C₁, C₂, C₃, C₄ are coefficients.

Further, this can be classified into grades according to the SCORE calculated in step S132.

For example, if the SCORE is less than 0.4, it is determined that the danger degree due to impact of the battery module is “safe”; if the SCORE is greater than 0.6, it is determined that the danger degree due to impact of the battery module is “dangerous”; and if the SCORE is 0.4 or more and 0.6 or less, determination of the danger degree due to impact of the battery module may be suspended. This is an example, and the present disclosure is not limited to those set forth above.

For example, the grade of danger degree may be classified into a different number of grades instead of the three mentioned above, and the range in which the SCORE calculated according to the coefficient value set in Mathematical Equation 5 is scaled also differs. Therefore, various changes and variations can be made, for example, the standard value for dividing grades may be a value other than 0.4 and 0.6 mentioned above.

The method of predicting the analysis result of the impact on the battery module using the impact analysis model of the battery module according to the present disclosure shows a matching rate of about 90% or more compared to the conventional finite element analysis technique. On the other hand, it is possible to rapidly predict the impact stability of the battery module relative to the conventional technique, and as a result, the design and development of the electrode module can be carried out efficiently. In addition, it makes it possible to standardize the conditions and prediction results for the impact stability of the battery module. Accordingly, reliability of the quality of the manufactured battery modules can be ensured.

Although aspects in this disclosure have been described in detail above with reference to preferred embodiments thereof, it will be appreciated by those skilled in the art that the scope of the present disclosure is not limited thereto, and various modifications and improvements can be made in these embodiments without departing from the principles and sprit of the disclosure, the scope of which is defined in the appended claims and their equivalents. For example, the method for learning an analysis model of an impact on a battery module and the method for predicting an analysis result of the impact on the battery module according to the present disclosure can be applied not only to battery modules, but also to battery cells, battery cell stacks, or battery packs.

### DESCRIPTION OF REFERENCE NUMERALS

100: battery module evaluation system
110: data input unit
120: data processing unit
130: data output unit
140: data storage unit

1. A method for predicting an analysis result of an impact on a battery module performed by a battery module evaluation system that comprises an impact analysis model, the method comprising the steps of:
receiving, by the impact analysis model, inputs identifying an initial state value corresponding to the battery module and an impact value derived in response to the impact applied to the battery module; and
predicting, by the impact analysis model, an analysis result of the impact applied to the of the battery module based, at least in part, on the initial state value and the impact value.

2. The method of claim 1,
further comprising:
executing a learning procedure to derive the impact analysis model of the battery module evaluation system,
wherein executing the learning procedure comprises:
executing a sampling step that samples initial state values corresponding to one or more battery modules and deformed state values corresponding to the one or more battery modules, wherein the deformed state values are determined based on impact values derived in response to impacts applied to the one or more battery modules;
repeating the sampling step during a predetermined test period to acquire learning data; and
applying a machine learning process to derive the impact analysis model for analyzing the battery module based, at least in part, on the learning data, wherein the machine learning process utilizes the initial state values and the deformed state values for the one or more battery modules to train the impact analysis model to predict the analysis result of the battery module due to the impact.

3. The method of claim 2, wherein
the sampling step comprises:
measuring and storing the initial state values for the one or more battery modules;
storing the impact values correspond to the one or more battery modules; and
measuring and storing the deformed state values for the one or more battery modules derived in response to the impacts to the one or more battery modules.

4. The method of claim 1, wherein
predicting the analysis result of the battery module comprises predicting a deformed state value of the battery module due to the impact.

5. The method of claim 4, further comprising:
predicting a strain of the battery module based, at least in part, on the deformed state value of the battery module.

6. The method of claim 4, wherein
the initial state value of the battery module is derived from a predetermined portion of the battery module, and the deformed state value of the battery module is derived from the predetermined portion of the battery module.

7. The method of claim 5, wherein
the strain of the battery module corresponds to a plastic strain of the battery module due to the impact.

8. The method of claim 5, wherein
the strain of the battery module corresponds to a strain of a predetermined portion of the battery module.

9. The method of claim 7, wherein:
the strain (εₚ) of the battery module is a value obtained by subtracting an elastic strain (εₑ) from a total strain (ε) at a time of impact of the battery module, and is calculated according to the following equations:
$${ε}_{p} = ε - {ε}_{e} ;$$
$$ε = {\int }_{{L}_{0}}^{L} \frac{dL}{L} = ln ( \frac{L}{{L}_{0}} ) ; and$$
$${ε}_{e} = σ / E ;$$
wherein, L₀ is a dimension of the battery module before deformation, L is a dimension of the battery module after deformation, σ is a stress value when a material is in its elastic limit state, and E is an elastic modulus of the material.

10. The method of claim 5,
further comprising:
predicting a SCORE indicating a danger degree of the battery module based on the strain of the battery module.

11. The method of claim 10, wherein
the SCORE indicating the danger degree of the battery module is calculated according to the following equation:
$$( SCORE ) = 1 / ( 1 + Exp ( - 645.62 {ε}_{p}^{3} + 312.85 {ε}_{p}^{2} - 61.417 {ε}_{p} + 2.9444 ) )$$
wherein, the SCORE is a value between 0 and 1.

12. The method of claim 11, wherein:
if the SCORE is less than 0.4, the danger degree due to the impact of the battery module is determined to be a first safety rating indicating a safe state for the battery module;
if the SCORE is greater than 0.6, the danger degree due to the impact of the battery module is determined to be a second safety rating indicating a dangerous state for the battery module;” and
if the SCORE is equal to or falls with a range of 0.4 and 0.6, a determination of the danger degree due to impact of the battery module is suspended.

13. The method of claim 1, wherein:
the initial state value of the battery module comprises an initial dimension value corresponding to the battery module;
the impact value comprises a deformed state value corresponding to the battery module; and
the deformed state value of the battery module comprises a deformed dimension value derived after deformation of the battery module.

14. The method of claim 13, wherein
the initial dimension value of the battery module includes at least one of a length, a width, a height, an upper face thickness, a lower face thickness, and a side face thickness of a predetermined portion of the battery module.

15. The method of claim 1, wherein
the initial state value of the battery module indicates at least one of a density of battery cells included in the battery module and a mass of the battery cells.

16. The method of claim 1, wherein
the impact value applied to the battery module includes at least one of an impact size and a duration during which the impact is applied.

17. A battery module evaluation system configured to predict an analysis result of an impact on a battery module, the battery module evaluation system comprising:
a data input unit that receives inputs indicating an initial state value of the battery module and an impact value derived in response to an impact applied to the battery module;
a data processing unit that executes an impact analysis model of the battery module to derive an analysis result of the impact based, at least in part, on the initial state value and the impact value; and
a data output unit that outputs the analysis result of the battery module.

18. The battery module evaluation system according to claim 17, further comprising a data storage unit that stores the impact analysis model of the battery module.

19.-34. (canceled)
